(19) United States
(12) Patent Application Publication
(10) Pub. No.: US 2026/0122869 A1
(43) Pub. Date: Apr. 30, 2026

(54) ELECTROMAGNETIC WAVE ABSORBING SHEET, A METHOD FOR MANUFACTURING AN ELECTROMAGNETIC WAVE ABSORBING SHEET, AND A CABLE COMPRISING THE ELECTROMAGNETIC WAVE ABSORBING SHEET

(71) Applicants: HYUNDAI MOTOR COMPANY, Seoul (KR); KIA CORPORATION, Seoul (KR)

(72) Inventors: Miru Kim, Hwaseong-si (KR); Woongui Hwang, Hwaseong-si (KR); Won Ju Lee, Gimpo-si (KR)

(73) Assignees: HYUNDAI MOTOR COMPANY, Seoul (KR); KIA CORPORATION, Seoul (KR)

(21) Appl. No.: 19/067,068

(22) Filed: Feb. 28, 2025

(30) Foreign Application Priority Data
Oct. 25, 2024 (KR) 10-2024-0147365

(51) Int. Cl. H05K 9/00; H01F 1/20

(52) U.S. Cl. CPC H05K 9/0084; H01F 1/20; H05K 9/0098

(57) ABSTRACT

An electromagnetic wave absorbing sheet includes magnetic powders oriented in one direction. A method for manufacturing an electromagnetic wave absorbing sheet includes preparing an electromagnetic wave absorbing composition comprising magnetic powders; and forming the electromagnetic wave absorbing composition on a base material. In forming the electromagnetic wave absorbing composition on the base material, the magnetic powders is oriented. A cable includes a conductor, and an electromagnetic wave absorbing sheet which is disposed on the conductor and includes magnetic powders. The magnetic powders is oriented in one direction in the electromagnetic wave absorbing sheet.

### CROSS-REFERENCE TO RELATED APPLICATION

This application claims the benefit of and priority to Korean Patent Application No. 10-2024-0147365, filed on Oct. 25, 2024, in the Korean Intellectual Property Office, the entire disclosure of which is incorporated herein by reference.

### TECHNICAL FIELD

The present disclosure relates to an electromagnetic wave absorbing sheet, a method for manufacturing an electromagnetic wave absorbing sheet, and a cable comprising the electromagnetic wave absorbing sheet.

### BACKGROUND

Electromagnetic shielding plays an important role in protecting electronic devices, equipment, and systems, from harmful effects of the electromagnetic interference (EMI). The electromagnetic wave may be shielded by electromagnetic wave absorption or electromagnetic wave reflection.

In the related art, most techniques use the electromagnetic wave reflection. However, when the electromagnetic wave is reflected to be shielded, the electromagnetic waves generated inside permeate inside again and become a noise or affect another element. Alternatively, the wavelengths of the electromagnetic waves overlap due to secondary or multiple N-order reflection and cause the influence of unexpected electromagnetic waves.

The statements in this Background section merely provide background information related to the present disclosure and may not constitute prior art.

### SUMMARY

In view of the foregoing, a technique of shielding the electromagnetic wave by the electromagnetic wave absorption is necessary.

According to an embodiment of the present disclosure, an electromagnetic wave absorbing sheet which effectively shields the electromagnetic wave by the electromagnetic wave absorption, a method for manufacturing an electromagnetic wave absorbing sheet, and a cable including an electromagnetic wave absorbing sheet may be provided.

An electromagnetic wave absorbing sheet according to an embodiment of the present disclosure includes magnetic powders oriented in a direction.

According to an embodiment of the present disclosure, the magnetic powders may be oriented in a same magnetization direction.

According to an embodiment of the present disclosure, the magnetic powder may include at least any one of sendust powder, ferrite powder, chromium powder, carbonyl iron powder, or nanocrystalline ribbon powder.

According to an embodiment of the present disclosure, an average particle size D50 of the magnetic powders is in a range of 10 μm to 70 μm.

According to an embodiment of the present disclosure, the magnetic powders may be included in an amount in a range of 80 wt % to 90 wt % based on a weight of the electromagnetic wave absorbing sheet.

According to an embodiment of the present disclosure, the magnetic powders may have a planar type.

An electromagnetic wave absorbing sheet according to an embodiment of the present disclosure may include a base material, and an electromagnetic wave absorbing layer including the magnetic powders. A thickness of the electromagnetic wave absorbing layer may be in a range of 100 μm to 300 μm.

A method for manufacturing an electromagnetic wave absorbing sheet according to an embodiment of the present disclosure includes preparing an electromagnetic wave absorbing composition including magnetic powders; and forming the electromagnetic wave absorbing composition on a base material. In forming the electromagnetic wave absorbing composition on the base material, the magnetic powders is oriented.

According to an embodiment of the present disclosure, forming the electromagnetic wave absorbing composition on the base material may include applying a magnetic field to the electromagnetic wave absorbing composition.

According to an embodiment of the present disclosure, the magnetic flux density of the magnetic field may be in a range of 0.25 T to 0.50 T.

According to an embodiment of the present disclosure, forming the electromagnetic wave absorbing composition on the base material may include applying a pressure to the electromagnetic wave absorbing composition.

According to an embodiment of the present disclosure, in forming the electromagnetic wave absorbing composition on the base material, the magnetic powders may be oriented in a same magnetization direction.

According to an embodiment of the present disclosure, the magnetic powders may include at least any one of sendust powder, ferrite powder, chromium powder, carbonyl iron powder, or nanocrystalline ribbon powder.

According to an embodiment of the present disclosure, the magnetic powders may have a planar shape.

A cable according to an embodiment of the present disclosure includes a conductor; and an electromagnetic wave absorbing sheet which is disposed on the conductor and includes magnetic powders. The magnetic powders is oriented in a direction in the electromagnetic wave absorbing sheet.

According to an embodiment of the present disclosure, the magnetic powders may be oriented in a direction intersecting the current direction of the conductor.

According to an embodiment of the present disclosure, the magnetic powders may be oriented in a direction corresponding to a magnetic induction direction formed by the conductor.

According to an embodiment of the present disclosure, the magnetic powders may include at least any one of sendust powder, ferrite powder, chromium powder, carbonyl iron powder, or nanocrystalline ribbon powder.

According to an embodiment of the present disclosure, the magnetic powders may have a planar shape.

According to an embodiment of the present disclosure, the magnetic powders may be included in an amount in a range of 80 wt % to 90 wt % based on a weight of the electromagnetic wave absorbing sheet.

### BRIEF DESCRIPTION OF THE DRAWINGS

The above and other aspects, features, and advantages of the present disclosure should become more apparent from the detailed description of the following aspects in conjunction with the accompanying drawings, in which:

FIG. 1 is a perspective view and an enlarged view of an electromagnetic wave absorbing sheet according to various embodiments of the present disclosure;

FIG. 2 is a schematic view for explaining a step of applying a magnetic field in a method for manufacturing an electromagnetic wave absorbing sheet according to various embodiments of the present disclosure;

FIGS. 3 and 4 are schematic views for explaining a step of applying a pressure in a method for manufacturing an electromagnetic wave absorbing sheet according to various embodiments of the present disclosure;

FIG. 5 is a perspective view of a cable according to various embodiments of the present disclosure;

FIG. 6 is a perspective view and an enlarged view of a cable according to various embodiments of the present disclosure;

FIG. 7 is an enlarged view of a cable according to various embodiments of the present disclosure;

FIGS. 8 and 9 are views for explaining an electromagnetic attenuation effect according to an orientation when an electromagnetic wave absorbing sheet is disposed on a conductor;

FIG. 10 is a graph of a permeability according to a magnetic flux density of Example and Comparative Examples;

FIG. 11 is an SEM image for identifying a cross-section of an electromagnetic wave absorbing sheet according to Comparative Example 1;

FIG. 12 is an SEM image for identifying a cross-section of an electromagnetic wave absorbing sheet according to Example 1;

FIG. 13 is an SEM image for identifying a cross-section of an electromagnetic wave absorbing sheet according to Example 2;

FIG. 14 is a graph of a permeability according to an average particle size D50 of magnetic powders and a thickness of an electromagnetic wave absorbing layer of Example and Comparative Examples;

FIG. 15 is a photograph of an Epstein frame device;

FIG. 16 is a schematic view for explaining a configuration of an Epstein frame;

FIGS. 17 and 18 are views for explaining a sample used for Experimental Example;

FIG. 19 is a schematic diagram for explaining magnetic characteristic evaluation for a first sample sheet;

FIG. 20 is a schematic diagram for explaining magnetic characteristic evaluation for a second sample sheet;

FIG. 21 is a result obtained by measuring a magnetic flux density and a permeability property of a first sample sheet and a second sample sheet;

FIG. 22 is a photograph illustrating an experimental configuration for verifying an effect according to whether to apply an electromagnetic wave absorbing sheet;

FIG. 23 is a spectrum analysis result of a cable to which an electromagnetic wave absorbing sheet is not applied; and

FIG. 24 is a spectrum analysis result of a cable to which an electromagnetic wave absorbing sheet according to an embodiment is applied.

The drawings described herein are for illustration purposes only and are not intended to limit the scope of the present disclosure in any way.

### DETAILED DESCRIPTION

Hereinafter, embodiments disclosed in the present specification are described in detail with reference to the accompanying drawings in detail. In the following description, the same or similar components are denoted by the same or similar reference numerals and a redundant description thereof may be omitted.

In this specification, the terms “comprises,” “comprising,” “including,” and “having,” are inclusive and therefore specify the presence of stated features, integers, steps, operations, elements, components or combinations thereof, but do not preclude any one of other features, integers, steps, operations, elements, components, and/or combinations thereof.

In the present disclosure, each of phrases such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases.

### Electromagnetic Wave Absorbing Composition

Various embodiments of the present disclosure relate to an electromagnetic wave absorbing composition.

The electromagnetic wave absorbing composition according to various embodiments of the present disclosure may comprise a magnetic powder, a solvent, and a binder.

The magnetic powder may be at least any one selected from the group consisting of sendust powder, ferrite powder, chromium powder, carbonyl iron powder, and nanocrystalline ribbon powder. Desirably, the magnetic powder may be a sendust powder. The sendust powder may be an alloy powder of 85% of Fe, 9% of Si, and 6% of Al.

An average particle size D50 of the magnetic powders is 10 to 70 μm. When the average particle size D50 of the magnetic powders is 10 to 70 μm, it is advantageous for orientation of the powders. When the average particle size of the magnetic powders is 10 to 70 μm, a permeability of the electromagnetic wave absorbing composition may be increased. Desirably, an average particle size D50 of the magnetic powders is 30 to 70 μm. More desirably, an average particle size D50 of the magnetic powders is 50 to 70 μm.

The magnetic powder may be a planar type. The magnetic powder may have a planar flake shape.

The magnetic powder may be comprised in an amount of 80 wt % to 90 wt % on the basis of the entire electromagnetic wave absorbing composition. When the magnetic powder is comprised in an amount of 80 wt % to 90 wt % on the basis of the entire electromagnetic wave absorbing composition, a high permeability may be achieved in a high frequency band.

The solvent may be at least any one selected from a group consisting of benzene, chlorobenzene, toluene, methyl ethyl ketone (MEK), and dimethyl formamide (DMF). In the solvent, a magnetic powder and a binder may be mixed. The solvent may adjust a viscosity of an electromagnetic wave absorbing composition.

The solvent may be comprised in an amount of less than 1 wt % on the basis of the entire electromagnetic wave absorbing composition.

The binder may be at least any one selected from a group consisting of polyurethane (TPU), acrylic resin, and epoxy resin. The binder may occupy the remaining composition other than the magnetic powder and the solvent in the entire electromagnetic wave absorbing composition.

The electromagnetic wave absorbing composition according to various embodiments of the present disclosure has a high permeability in a high frequency band. The electromagnetic wave absorbing composition according to various embodiments of the present disclosure has an excellent electromagnetic shielding effect. The electromagnetic wave absorbing composition according to various embodiments of the present disclosure has an excellent electromagnetic wave absorbing effect. The electromagnetic wave absorbing composition according to various embodiments of the present disclosure may effectively shield the electromagnetic interference. The electromagnetic wave absorbing composition according to various embodiments of the present disclosure may be applied to various cables, conducting wires, electric wires, and the like which require the electromagnetic wave shielding.

### Electromagnetic Wave Absorbing Sheet

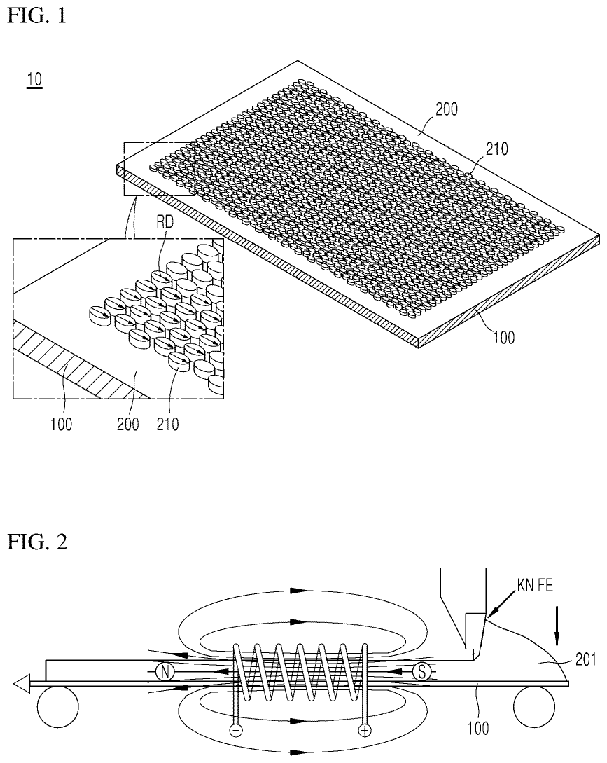

The electromagnetic wave absorbing sheet according to various embodiments of the present disclosure may be manufactured from the electromagnetic wave absorbing composition described above. FIG. 1 is a perspective view and an enlarged view of an electromagnetic wave absorbing sheet according to various embodiments of the present disclosure.

Referring to FIG. 1, an electromagnetic wave absorbing sheet 10 according to various embodiments of the present disclosure may comprise a base material 100 and an electromagnetic wave absorbing layer 200.

The base material 100 may be a polymer film. The base material 100 may be any one selected from a group consisting of a PET (polyethylene terephthalate) sheet, a PI (polyimide) sheet, and a PE (polyethylene) sheet.

The electromagnetic wave absorbing layer 200 may be manufactured from the above-described electromagnetic wave absorbing composition. The electromagnetic wave absorbing layer 200 may comprise magnetic powders 210. The electromagnetic wave absorbing layer 200 may comprise magnetic powders 210 and a binder. The electromagnetic wave absorbing layer 200 may be manufactured from the above-described electromagnetic wave absorbing composition and a solvent may be in a volatile state.

The magnetic powders 210 may be oriented in one direction RD in the electromagnetic wave absorbing layer 200. The magnetic powders 210 may be oriented in a predetermined direction in the electromagnetic wave absorbing layer 200. The magnetic powders 210 may be oriented in the same direction in the electromagnetic wave absorbing layer 200.

The magnetic powders 210 may be oriented in a predetermined magnetization direction in the electromagnetic wave absorbing layer 200. The magnetic powders 210 may be oriented in the same magnetization direction in the electromagnetic wave absorbing layer 200.

The magnetic powders 210 may be oriented in a casting direction during the formation of the electromagnetic wave absorbing layer 200. The magnetic powders 210 may be oriented along a casting direction during the formation of the electromagnetic wave absorbing layer 200.

The magnetic powders 210 may be at least any one selected from the group consisting of sendust powder, ferrite powder, chromium powder, carbonyl iron powder, and nanocrystalline ribbon powder. Desirably, the magnetic powder 210 may be a sendust powder. The sendust powder may be an alloy powder of 85% of Fe, 9% of Si, and 6% of Al.

An average particle size D50 of the magnetic powders 210 is 10 to 70 μm. When the average particle size D50 of the magnetic powders 210 is 10 to 70 μm, it is advantageous for orientation of the powders. When the average particle size of the magnetic powders 210 is 10 to 70 μm, a permeability of the electromagnetic wave absorbing sheet 10 may be increased. Desirably, an average particle size D50 of the magnetic powders 210 is 30 to 70 μm. More desirably, an average particle size D50 of the magnetic powders 210 is 50 to 70 μm.

The magnetic powder 210 may be a planar shape. The magnetic powder 210 may have a planar flake shape. The planar surface of the magnetic powder 210 may be oriented in a direction horizontal to the electromagnetic wave absorbing sheet 10.

The magnetic powder 210 may be comprised in an amount of 80 wt % to 90 wt % on the basis of the entire electromagnetic wave absorbing sheet 10. When the magnetic powder 210 is comprised in the amount of 80 wt % to 90 wt % on the basis of the entire electromagnetic wave absorbing sheet 10, a high permeability may be achieved in a high frequency band.

The binder may be at least any one selected from a group consisting of polyurethane (TPU), acrylic resin, and epoxy resin. The binder may be comprised in an amount of 10 wt % to 20 wt % on the basis of the entire electromagnetic wave absorbing sheet 10.

A thickness of the electromagnetic wave absorbing layer 200 may be 100 μm to 300 μm. When the thickness of the electromagnetic wave absorbing layer 200 is smaller than 100 μm, the electromagnetic wave absorbing effect may be degraded. When the thickness of the electromagnetic wave absorbing layer 200 is larger than 200 μm, a planar surface of some magnetic powder is oriented in a direction transverse to the electromagnetic wave absorbing sheet so that the permeability may be degraded. Desirably, a thickness of the electromagnetic wave absorbing layer 200 may be 100 to 200 μm.

The electromagnetic wave absorbing sheet according to various embodiments of the present disclosure has a high permeability in a high frequency band. The electromagnetic wave absorbing sheet according to various embodiments of the present disclosure has an excellent electromagnetic shielding effect. The electromagnetic wave absorbing sheet according to various embodiments of the present disclosure has an excellent electromagnetic wave absorbing effect. The electromagnetic wave absorbing sheet according to various embodiments of the present disclosure may be applied to various cables, conducting wires, electric wires, and the like which require the electromagnetic wave shielding.

When the electromagnetic wave absorbing sheet according to various embodiments of the present disclosure is applied to the cable, the conducting wire, and the electric wire, the electromagnetic wave absorbing sheet may absorb the electromagnetic wave of the conductor. The electromagnetic wave absorbing sheet may suppress the magnetic field interference induced by the conductor. The electromagnetic wave absorbing sheet may attenuate an electromagnetic wave radiated from a signal and/or a power, such as the cable, the conducting wire, and the electric wire, by absorbing the magnetic field. When the magnetic field absorption is dominant, the electromagnetic wave absorbing sheet may effectively shield the electromagnetic interference.

### Method for Manufacturing Electromagnetic Wave Absorbing Sheet

A method for manufacturing an electromagnetic wave absorbing sheet according to various embodiments of the present disclosure may comprise a step of preparing an electromagnetic wave absorbing composition comprising a magnetic powder; and a step of forming an electromagnetic wave absorbing composition on a base material.

The method for manufacturing an electromagnetic wave absorbing sheet according to various embodiments of the present disclosure may manufacture an electromagnetic wave absorbing sheet comprising a base material and an electromagnetic wave absorbing layer.

In the step of preparing an electromagnetic wave absorbing composition, the above-described electromagnetic wave absorbing composition may be prepared. In the step of preparing an electromagnetic wave absorbing composition, an electromagnetic wave absorbing composition comprising a magnetic powder, a solvent, and a binder may be prepared.

The magnetic powder may be at least any one selected from the group consisting of sendust powder, ferrite powder, chromium powder, carbonyl iron powder, and nanocrystalline ribbon powder. Desirably, the magnetic powder may be a sendust powder. The sendust powder may be an alloy powder of 85% of Fe, 9% of Si, and 6% of Al.

An average particle size D50 of the magnetic powders is 10 to 70 μm. When the average particle size D50 of the magnetic powders is 10 to 70 μm, it is advantageous for orientation of the powders. When the average particle size of the magnetic powders is 10 to 70 μm, a permeability of the electromagnetic wave absorbing sheet may be increased. Desirably, an average particle size D50 of the magnetic powders may be 30 to 70 μm. More desirably, an average particle size D50 of the magnetic powders may be 50 to 70 μm.

The magnetic powder may be a planar type. The magnetic powder may have a planar flake shape.

The magnetic powder may be comprised in an amount of 80 wt % to 90 wt % on the basis of the entire electromagnetic wave absorbing composition. When the magnetic powder is comprised in an amount of 80 wt % to 90 wt % on the basis of the entire electromagnetic wave absorbing composition, a high permeability may be achieved in a high frequency band.

The solvent may be at least any one selected from a group consisting of benzene, chlorobenzene, toluene, methyl ethyl ketone (MEK), and dimethyl formamide (DMF). In the solvent, a magnetic powder and a binder may be mixed. The solvent may adjust a viscosity of the electromagnetic wave absorbing composition.

The solvent may be comprised in an amount of less than 1 wt % on the basis of the entire electromagnetic wave absorbing composition.

The binder may be at least any one selected from a group consisting of polyurethane (TPU), acrylic resin, and epoxy resin.

In the step of forming an electromagnetic wave absorbing composition on a base material, the above-described electromagnetic wave absorbing composition is applied on the base material to be formed as a sheet. In the step of forming an electromagnetic wave absorbing composition on a base material, an electromagnetic wave absorbing layer may be formed on the base material.

The base material may be a polymer film. For example, the base material may be any one selected from a group consisting of a PET sheet, a PI sheet, and a PE sheet.

In the step of forming an electromagnetic wave absorbing composition on a base material, the electromagnetic wave absorbing composition may be coated on the base material by at least any one method selected from a group consisting of knife coating, calendar coating, roll coating, and casting coating.

The knife coating may be a coating method of applying the electromagnetic wave absorbing composition on the base material as a film type while cutting the electromagnetic wave absorbing composition with a knife. At this time, the thickness of the electromagnetic wave absorbing layer may be adjusted by adjusting the position and/or the angle of the knife. A temperature of the electromagnetic wave absorbing composition may be 20 to 40° C.

However, the temperature of the electromagnetic wave absorbing composition may be adjusted according to the viscosity. An applied pressure may vary according to the viscosity of the electromagnetic wave absorbing composition and/or a thickness of an electromagnetic wave absorbing layer to be formed. For example, the applied pressure may be 0.1 to 1 MPa.

The calendar coating may be a coating method of applying an electromagnetic wave absorbing composition on a base material, and then applying a pressure by allowing the electromagnetic wave absorbing composition to pass between two rollers. The thickness of an electromagnetic wave absorbing layer may be adjusted by adjusting a temperature, a rotation speed, and a pressure of the roller.

The step of forming an electromagnetic wave absorbing composition on a base material may comprise a step of applying a magnetic field to the electromagnetic wave absorbing composition. Specifically, in the step of applying a magnetic field, the magnetic field may be applied when the electromagnetic wave absorbing composition is coated by knife coating, calendar coating, roll coating, or casting coating.

In the step of applying a magnetic field, the magnetic flux density of the magnetic field may be 0.25 T or higher. Desirably, the magnetic flux density of the magnetic field may be 0.25 T to 0.50 T. When the magnetic flux density is 0.25 T or higher, the permeability of the electromagnetic wave absorbing sheet may be improved. In contrast, when the magnetic flux density exceeds 0.50 T, the effect of improving the permeability may not be significant.

FIG. 2 is a schematic view for explaining a step of applying a magnetic field in a method for manufacturing an electromagnetic wave absorbing sheet according to various embodiments of the present disclosure. Referring to FIG. 2, in order to apply a magnetic field, the base material 100 to which the electromagnetic wave absorbing composition 201 is applied may pass through a magnetic field driving device. For example, the magnetic field driving device may be a solenoid device. In the solenoid device, a magnetic flux density may be adjusted by means of the length of a winding unit, the number of windings, and/or an intensity of a current. In other words, a magnetic flux density may be adjusted to be 0.25 T or higher by means of the length of a winding unit, the number of windings, and/or an intensity of a current.

In the step of applying a magnetic field, magnetic powders comprised in the electromagnetic wave absorbing composition 201 may be oriented by an external magnetic field.

In the meantime, according to still another embodiment, the step of forming an electromagnetic wave absorbing composition on a base material may comprise a step of applying a pressure to the electromagnetic wave absorbing composition.

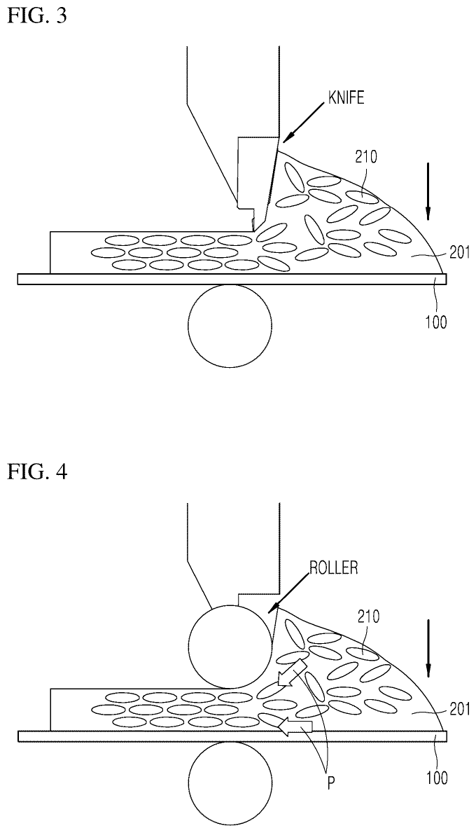

FIGS. 3 and 4 are schematic views for explaining a step of applying a pressure in a method for manufacturing an electromagnetic wave absorbing sheet according to various embodiments of the present disclosure. Referring to FIG. 3, in the step of applying a pressure, when the electromagnetic wave absorbing composition 201 is coated by knife coating, a pressure may be applied to a knife. By doing this, when the magnetic powders 210 comprised in the electromagnetic wave absorbing composition 201 are ejected in the rolling direction, the magnetic powders may be oriented to reduce resistance.

Referring to FIG. 4, in the step of applying a pressure, when the electromagnetic wave absorbing composition 201 is coated by calendar coating, a pressure P may be applied to a roller. By doing this, when the magnetic powders 210 comprised in the electromagnetic wave absorbing composition 201 are ejected in the rolling direction, the magnetic powders may be oriented to reduce resistance.

In the step of forming an electromagnetic wave absorbing composition on a base material, the magnetic powders in the electromagnetic wave absorbing composition may be oriented in one direction. In the step of forming an electromagnetic wave absorbing composition on a base material, the magnetic powders in the electromagnetic wave absorbing composition may be oriented in a predetermined direction. In the step of forming an electromagnetic wave absorbing composition on a base material, the magnetic powders in the electromagnetic wave absorbing composition may be oriented in the same direction. In the step of forming an electromagnetic wave absorbing composition on a base material, planar surfaces of the magnetic powders in the electromagnetic wave absorbing composition may be oriented in a direction parallel to the base material.

In the step of forming an electromagnetic wave absorbing composition on a base material, the magnetic powders in the electromagnetic wave absorbing composition may be oriented in a predetermined magnetization direction. In the step of forming an electromagnetic wave absorbing composition on a base material, the magnetic powders in the electromagnetic wave absorbing composition may be oriented in the same magnetization direction.

In the step of forming an electromagnetic wave absorbing composition on a base material, the magnetic powders may be oriented in a casting direction or a rolling direction. In the step of forming an electromagnetic wave absorbing composition on a base material, the planar surfaces of the magnetic powders may be oriented along a casting direction or a rolling direction.

According to the method for manufacturing an electromagnetic wave absorbing sheet according to various embodiments of the present disclosure, an electromagnetic wave absorbing sheet having a high permeability in a high frequency band may be manufactured. According to the method for manufacturing an electromagnetic wave absorbing sheet according to various embodiments of the present disclosure, an electromagnetic wave absorbing sheet having an excellent electromagnetic wave shielding effect may be manufactured. According to the method for manufacturing an electromagnetic wave absorbing sheet according to various embodiments of the present disclosure, an electromagnetic wave absorbing sheet having an excellent electromagnetic wave absorbing effect may be manufactured.

### Cable

A cable according to various embodiments of the present disclosure comprises the above-described electromagnetic wave absorbing sheet.

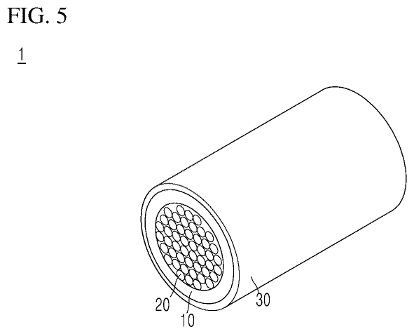

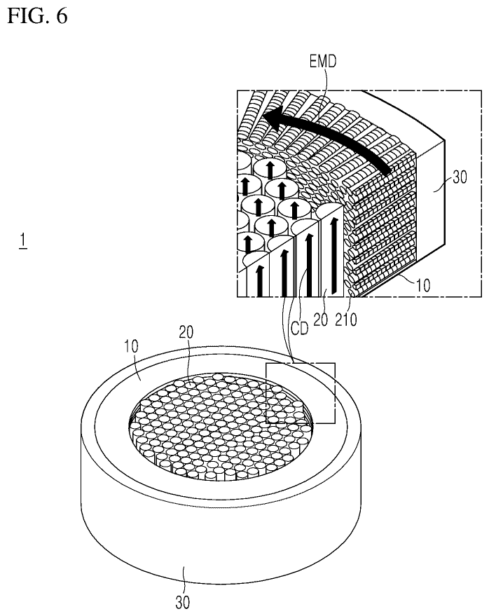

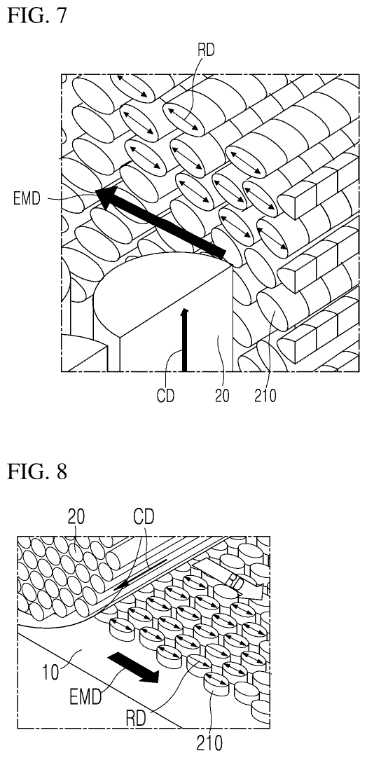

FIG. 5 is a perspective view of a cable according to various embodiments of the present disclosure. FIG. 6 is a perspective view and an enlarged view of a cable according to various embodiments of the present disclosure. FIG. 7 is an enlarged view of a cable according to various embodiments of the present disclosure.

Referring to FIGS. 5 and 6, a cable 1 according to various embodiments of the present disclosure may comprise a conductor 20, an electromagnetic wave absorbing sheet 10, and an insulating layer 30.

The conductor 20 may be a conducting wire and/or an electric wire through which a current flows. The conductor 20 may comprise a metal having conductivity. The conductor 20 may comprise at least any one selected from a group consisting of copper, aluminum, gold, silver, and iron-based alloy.

The electromagnetic wave absorbing sheet 10 may be disposed on the conductor 20. The electromagnetic wave absorbing sheet 10 may be disposed to surround the conductor 20. The electromagnetic wave absorbing sheet 10 may be disposed to enclose the conductor 20. The electromagnetic wave absorbing sheet 10 may embed the conductor 20.

The electromagnetic wave absorbing sheet 10 may absorb an electromagnetic wave of the conductor 20. The electromagnetic wave absorbing sheet 10 may suppress a magnetic field interference induced by the conductor 20. The electromagnetic wave absorbing sheet 10 may attenuate an electromagnetic wave radiated from a signal and/or a power of the cable 1 by absorbing the magnetic field. When the magnetic field absorption is dominant, the electromagnetic wave absorbing sheet 10 may effectively shield the electromagnetic interference.

The insulating layer 30 may be disposed on the electromagnetic wave absorbing sheet 10. The insulating layer 30 may be disposed to surround the conductor 20 and the electromagnetic wave absorbing sheet 10. The insulating layer 30 may be disposed to enclose the conductor 20 and the electromagnetic wave absorbing sheet 10. The insulating layer 30 may embed the conductor 20 and the electromagnetic wave absorbing sheet 10. The insulating layer 30 may be disposed at the outermost periphery of the cable 1.

The insulating layer 30 may protect and insulate the cable 1 from the outside.

The insulating layer 30 may comprise an insulating material. The insulating layer 30 may be a heat shrinkable tube. The insulating layer 30 may be an insulating coating. The insulating layer 30 may comprise at least any one selected from the group consisting of polyolefin, polyvinyl chloride (PVC), polytetrafluoroethylene (PTFE), silicone, and polyester.

Referring to FIGS. 6 and 7, the electromagnetic wave absorbing sheet 10 may comprise magnetic powders 210.

The magnetic powders 210 may be oriented in one direction in the electromagnetic wave absorbing sheet 10. The magnetic powders 210 may be oriented in a predetermined direction in the electromagnetic wave absorbing sheet 10. The magnetic powders 210 may be oriented in the same direction in the electromagnetic wave absorbing sheet 10. Planar surfaces of the magnetic powders 210 may be oriented in a direction parallel to the electromagnetic wave absorbing sheet 10.

The magnetic powders 210 may be oriented in a predetermined magnetization direction in the electromagnetic wave absorbing sheet 10. The magnetic powders 210 may be oriented in the same magnetization direction in the electromagnetic wave absorbing sheet 10.

The magnetic powder 210 may be at least any one selected from the group consisting of sendust powder, ferrite powder, chromium powder, carbonyl iron powder, and nanocrystalline ribbon powder. Desirably, the magnetic powder 210 may be a sendust powder. The sendust powder may be an alloy powder of 85% of Fe, 9% of Si, and 6% of Al.

An average particle size D50 of the magnetic powders 210 may be 10 to 70 μm. When the average particle size D50 of the magnetic powders 210 is 10 to 70 μm, it is advantageous for orientation of the powders. When the average particle size of the magnetic powders 210 is 10 to 70 μm, a permeability of the electromagnetic wave absorbing sheet 10 may be increased. Desirably, an average particle size D50 of the magnetic powders 210 may be 30 to 70 μm. More desirably, an average particle size D50 of the magnetic powders 210 may be 50 to 70 μm.

The magnetic powder 210 may be a planar shape. The magnetic powder 210 may have a planar flake shape.

The magnetic powder 210 may be comprised in an amount of 80 wt % to 90 wt % on the basis of the entire electromagnetic wave absorbing sheet 10. When the magnetic powder 210 is comprised in the amount of 80 wt % to 90 wt % based on the entire electromagnetic wave absorbing sheet 10, a high permeability may be achieved in a high frequency band.

Referring to FIGS. 6 and 7, in the conductor 20, a current and/or a signal may flow in a length direction of the conductor 20 and an electromagnetic wave may be formed in a direction enclosing the conductor 20.

The direction of the current and/or signal in the conductor 20 is denoted by a current direction CD. The direction of forming an electromagnetic wave by the conductor 20 is denoted by a magnetic induction direction EMD. The orientation direction of the magnetic powders 210 is denoted by a magnetization direction RD.

The magnetization direction RD of the magnetic powders 210 may correspond to the magnetic induction direction EMD. The magnetization direction RD of the magnetic powders 210 may be the same direction as the magnetic induction direction EMD. The magnetization direction RD of the magnetic powders 210 may be a direction parallel to the magnetic induction direction EMD.

The magnetization direction RD of the magnetic powders 210 may be a direction intersecting the current direction CD of the conductor 20. The magnetization direction RD of the magnetic powders 210 may be a direction transverse to the current direction CD of the conductor 20.

The electromagnetic wave absorbing sheet 10 may be disposed on the conductor 20 so as to allow the magnetization direction RD of the magnetic powders 210 to correspond to the magnetic induction direction EMD. The electromagnetic wave absorbing sheet 10 may be disposed on the conductor 20 so as to allow the magnetization direction RD of the magnetic powders 210 to be parallel to the magnetic induction direction EMD.

The electromagnetic wave absorbing sheet 10 may be disposed on the conductor 20 so as to allow the magnetization direction RD of the magnetic powders 210 to intersect the current direction CD of the conductor 20. The electromagnetic wave absorbing sheet 10 may be disposed on the conductor 20 so as to allow the magnetization direction RD of the magnetic powders 210 to be transverse to the current direction CD of the conductor 20. The electromagnetic wave absorbing sheet 10 may be disposed on the conductor 20 so as to allow the magnetization direction RD of the magnetic powders 210 to intersect the length direction of the conductor 20. The electromagnetic wave absorbing sheet 10 may be disposed on the conductor 20 so as to allow the magnetization direction RD of the magnetic powders 210 to be transverse to the length direction of the conductor 20.

The electromagnetic wave absorbing sheet 10 may effectively shield and/or absorb an electromagnetic wave formed by the conductor 20. The electromagnetic wave absorbing sheet 10 may effectively shield and/or absorb an electromagnetic wave radiated from the conductor 20. The electromagnetic wave absorbing sheet 10 may effectively attenuate the electromagnetic wave of the cable 1.

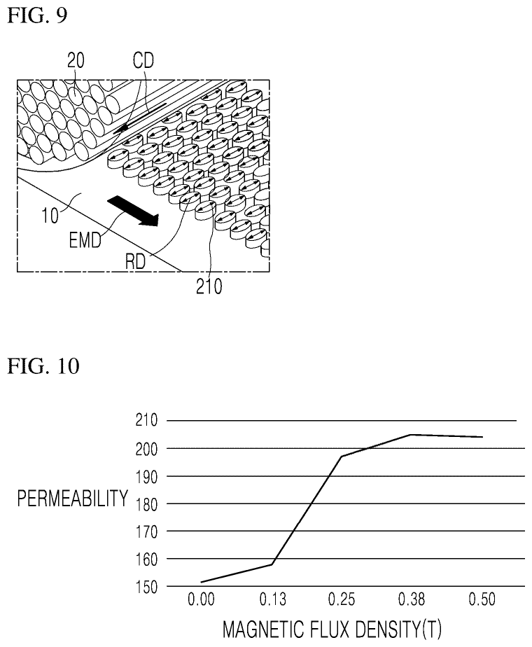

FIGS. 8 and 9 are views for explaining an electromagnetic attenuation effect according to an orientation when an electromagnetic wave absorbing sheet is disposed on a conductor.

FIG. 8 explains that an electromagnetic wave absorbing sheet is disposed according to Example of the present disclosure. FIG. 9 explains that an electromagnetic wave absorbing sheet is disposed according to Comparative Example.

Referring to FIG. 8, when the electromagnetic wave absorbing sheet 10 encloses the conductor 20 in a casting direction of the electromagnetic wave absorbing sheet 10, the magnetic induction direction EMD and the magnetization direction RD of the magnetic powders 210 may match. Accordingly, the electromagnetic attenuation characteristic may be excellent.

Referring to FIG. 9, when the electromagnetic wave absorbing sheet 10 encloses the conductor 20 in a direction intersecting the casting direction of the electromagnetic wave absorbing sheet 10, the magnetic induction direction EMD and the magnetization direction RD of the magnetic powders 210 may intersect. Accordingly, the electromagnetic attenuation characteristic may be degraded.

Hereinafter, embodiments of the present disclosure are described in more detail through Examples. However, the following Examples and Experimental Examples are provided to describe the present disclosure in more detail, but the scope of the present disclosure is not limited by the following Example and Experimental Examples.

### Example: Manufacturing of Electromagnetic Wave Absorbing Sheet

An electromagnetic wave absorbing composition comprising magnetic powders, a solvent, and a binder was prepared. As the magnetic powders, sendust powder (sendust flake) which was an alloy powder of 85% of Fe, 9% of Si, and 6% of Al was used. Toluene was used as the solvent and polyurethane resin was used as the binder. An electromagnetic wave absorbing composition in which 6.3 kg of sendust flake, 0.7 kg of polyurethane resin, and 8 kg of toluene were mixed was formed on a polymer film by knife coating. During this process, the polymer film and the electromagnetic wave absorbing composition passed into the solenoid device. As a result, an electromagnetic wave absorbing layer comprising magnetic powders was formed on the polymer film.

### Experimental Example 1: Confirmation of Permeability According to Magnetic Flux Density

The magnetic flux density (B) was changed by changing the current intensity of the solenoid device in Example as represented in Equation 1. By doing this, the permeability of the electromagnetic wave absorbing sheet formed by this was identified and the result was represented in the following Table 1.

TABLE 1

| | K″ (T · m/A) | N | I (A) | L (m) | B (T) | Permeability |
|---|---|---|---|---|---|---|
| Com. Ex. 1 | 1.26E−06 | 1,000 | 0 | 0.1 | 0.00 | 152 |
| Com. Ex. 2 | (4π · 10⁻⁷) | | 10 | | 0.13 | 158 |
| Example 1 | | | 20 | | 0.25 | 197 |
| Example 2 | | | 30 | | 0.38 | 205 |
| Com. Ex. 3 | | | 40 | | 0.50 | 204 |

$$\begin{matrix}B = \frac{{k}^{″} NI}{L} \\ K ” = 4 π \cdot {10}^{- 7} ( T \cdot m / A ) \\ I : Intensity of current \\ N : Total number of windings \\ L : Length of solenoid\end{matrix} \qquad Equation 1$$

FIG. 10 is a graph of permeability according to a magnetic flux density of Example and Comparative Examples.

Referring to Table 1 and FIG. 10, it is understood that as in Examples 1 and 2, when the magnetic flux densities are 0.25 T and 0.38 T, respectively, the permeability is significantly increased to be 190 or higher. In contrast, when the magnetic flux density was increased to 0.50 T as in Comparative Example 3, an increase rate of the permeability was insignificant. Accordingly, it was confirmed that the magnetic flux density which was the most efficient while maximizing the permeability was 0.25 T or higher and lower than 0.50 T.

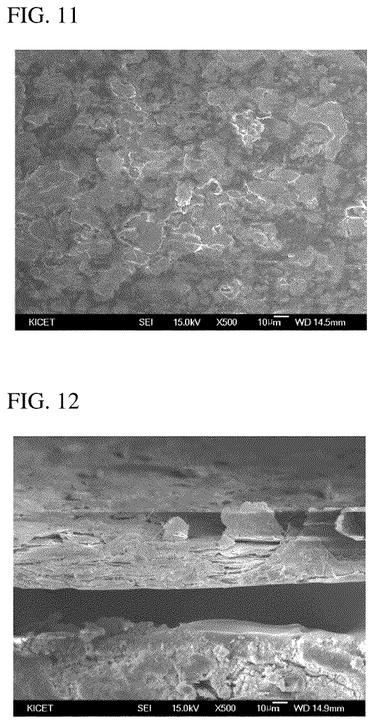

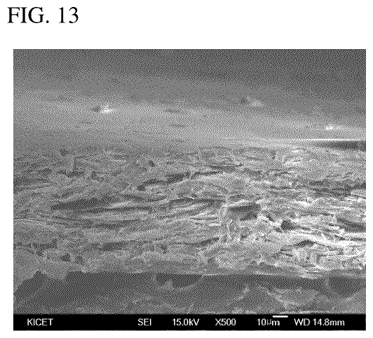

FIG. 11 is an SEM (scanning electron microscopy) image for identifying a cross-section of an electromagnetic wave absorbing sheet according to Comparative Example 1. FIG. 12 is an SEM image for identifying a cross-section of an electromagnetic wave absorbing sheet according to Example 1. FIG. 13 is an SEM image for identifying a cross-section of an electromagnetic wave absorbing sheet according to Example 2.

Referring to FIG. 11, as in Comparative Example 1, in the case of an electromagnetic wave absorbing sheet manufactured in a state in which a magnetic flux density was not applied, the orientation of the magnetic powders could not be observed. Referring to FIGS. 12 and 13, as in Examples 1 and 2, in the case of an electromagnetic wave absorbing sheet manufactured by applying an appropriate magnetic flux density, it was confirmed that the magnetic powders were oriented in a predetermined direction.

### Experimental Example 2: Identification of Permeability According to Size of Magnetic Powder and Thickness of Electromagnetic Wave Absorbing Layer

In the above Examples, after manufacturing by varying an average particle size D50 of magnetic powders and a thickness of an electromagnetic wave absorbing layer, each permeability was identified. The results were as represented in the following Table 2.

TABLE 2

| | Magnetic | Thickness of | |
|---|---|---|---|
| | powder | electromagnetic wave | |
| | D50 (μm) | absorbing layer (μm) | Permeability |
| Example 3 | 10 | 100 | 156 |
| Example 4 | 10 | 200 | 142 |
| Example 5 | 10 | 300 | 128 |
| Com. Ex. 4 | 10 | 400 | 124 |
| Example 6 | 30 | 100 | 172 |
| Example 7 | 30 | 200 | 168 |
| Example 8 | 30 | 300 | 148 |
| Com. Ex. 5 | 30 | 400 | 152 |
| Example 9 | 50 | 100 | 234 |
| Example 10 | 50 | 200 | 231 |
| Example 11 | 50 | 300 | 217 |
| Com. Ex. 6 | 50 | 400 | 212 |
| Example 12 | 70 | 100 | 297 |
| Example 13 | 70 | 200 | 281 |
| Example 14 | 70 | 300 | 249 |
| Com. Ex. 7 | 70 | 400 | 255 |

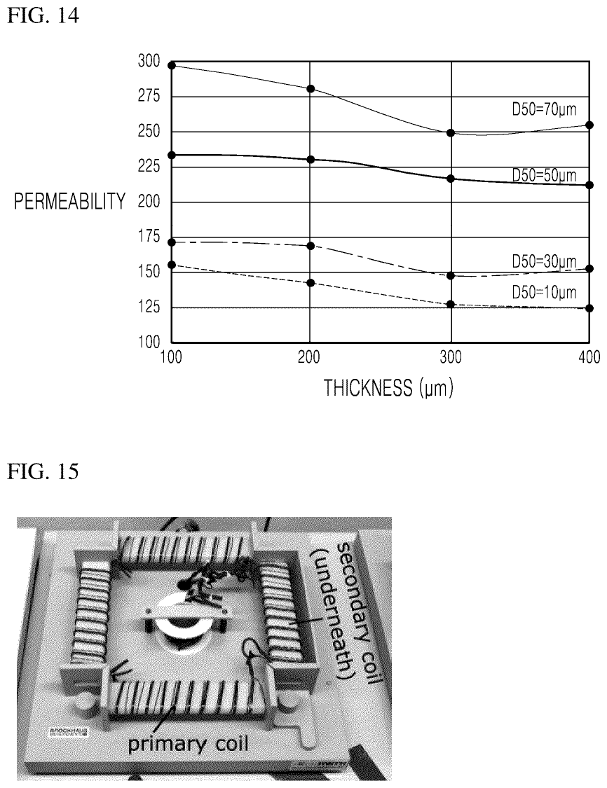

FIG. 14 is a graph of permeability according to an average particle size D50 of magnetic powders and the thickness of an electromagnetic wave absorbing layer of Example and Comparative Examples.

Referring to Table 2 and FIG. 14, it is understood that as the particles of the magnetic powders increase, the planar flake forms wider fragments to enable better orientation, which increases the permeability. Specifically, it is understood that when the average particle D50 of the magnetic powders is 50 to 70 μm, the permeability of the electromagnetic wave absorbing sheet is significantly improved.

In the meantime, when the thickness of the electromagnetic wave absorbing layer is increased, a planar surface may be oriented in a transverse direction to the sheet so that the permeability in a thick sheet may be lower than that in the sheet with a small thickness. Referring to Table 2 and FIG. 14, it was confirmed that when the thickness of the electromagnetic wave absorbing layer was 300 μm, the permeability was significantly reduced. Accordingly, it was confirmed that a desirable thickness of the electromagnetic wave absorbing layer which improved the permeability was 100 to 200 μm.

From the above result, it is understood that when the average particle size D50 of the magnetic powders is 50 to 70 μm and the thickness of the electromagnetic wave absorbing layer is 100 to 200 μm, the best permeability is achieved.

### Experimental Example 3: Identification of Permeability According to Casting Direction

A permeability characteristic of the electromagnetic wave absorbing sheet according to a casting direction was identified using an Epstein frame.

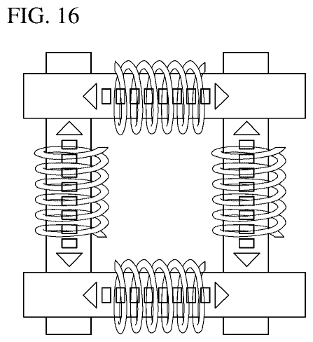

FIG. 15 is a photograph of an Epstein frame device. FIG. 16 is a schematic view for explaining a configuration of an Epstein frame. The Epstein frame is a jig that evaluates the magnetic characteristic of an evaluation material by placing rectangular sheet type materials overlapping each other in the form of “#” to form a closed magnetic circuit.

Referring to FIGS. 15 and 16, a primary coil and a secondary coil are wound so that an electromagnetic characteristic of the material with respect to an external magnetic field may be confirmed by means of a current applied through the primary coil and an electromagnetic voltage induced through the secondary coil.

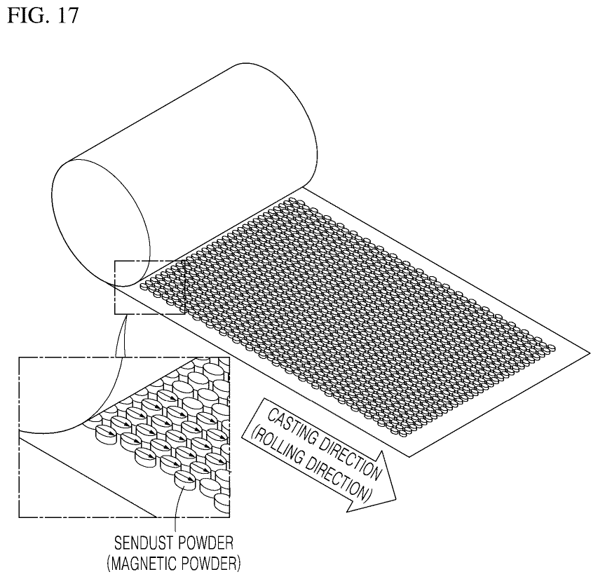

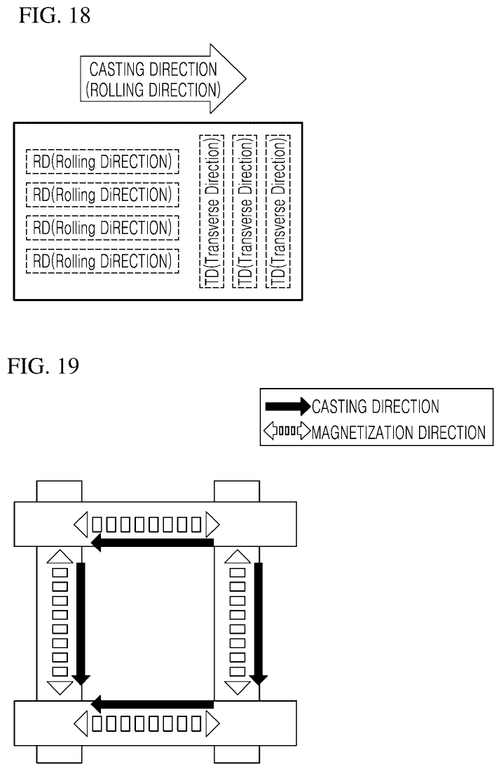

FIGS. 17 and 18 are views for explaining a sample used for Experimental Example. Referring to FIG. 17, when the electromagnetic wave absorbing composition is formed, the sendust powders (magnetic powders) are oriented according to the casting direction (rolling direction).

Referring to FIG. 18, a magnetic characteristic was evaluated using an Epstein frame using a first sample sheet comprising magnetic powders in the same direction as the casting direction and a second sample sheet comprising magnetic powders in a transverse direction to the casting direction.

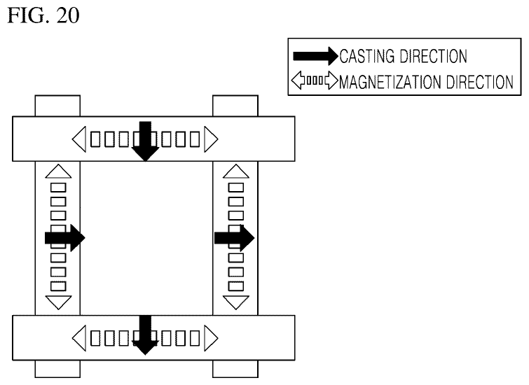

FIG. 19 is a schematic diagram for explaining magnetic characteristic evaluation for a first sample sheet. Referring to FIG. 19, a magnetization direction of the first sample sheet is parallel to the casting direction. FIG. 20 is a schematic diagram for explaining a magnetic characteristic evaluation for a second sample sheet. Referring to FIG. 20, the magnetization direction of the second sample sheet is transverse to the casting direction.

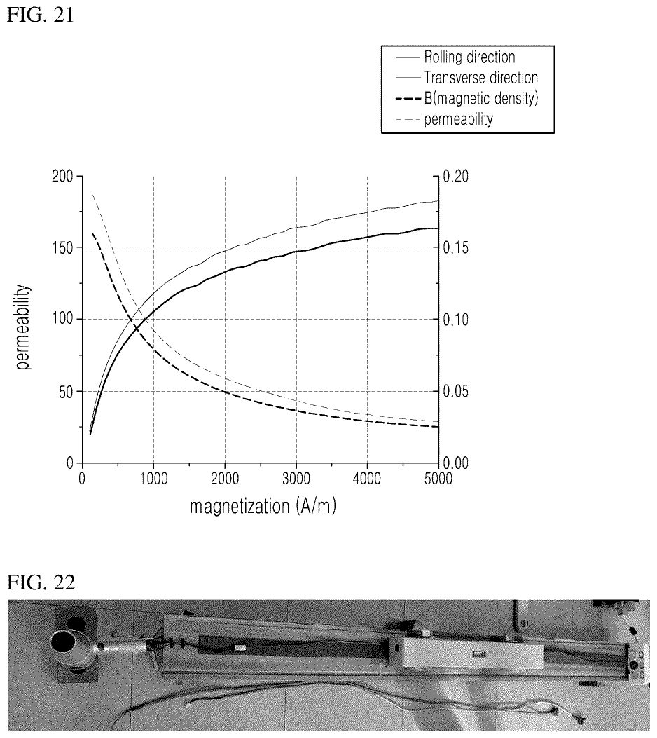

FIG. 21 is a result obtained by measuring a magnetic flux density and a permeability property of a first sample sheet and a second sample sheet.

Referring to FIG. 21, when the casting direction and the magnetization direction were horizontal (rolling direction) like the first sample sheet, the magnetic flux density and the permeability were high due to the orientation of the magnetic powders disposed in the easy magnetizing direction.

In contrast, when the magnetization direction was transverse to the casting direction like the second sample sheet, the orientation of the magnetic powders was different from the magnetization direction so that it was confirmed that the magnetic characteristic was much worse.

### Experimental Example 4: Identification of Effect of Absorbing Electromagnetic Wave

An effect of absorbing an electromagnetic wave by a cable to which an electromagnetic wave absorbing sheet according to an embodiment was applied was confirmed. For the sake of comparison, a cable to which an electromagnetic wave absorbing sheet according to an embodiment was not applied was also prepared.

FIG. 22 is a photograph illustrating an experimental configuration for verifying an effect according to whether to apply an electromagnetic wave absorbing sheet.

The device to operate is a dryer. When sheets were replaced with a cable (black) to which the electromagnetic wave absorbing sheet was not applied and with a cable (yellow or red) to which the electromagnetic wave absorbing sheet was applied, radiated electromagnetic waves were measured using a spectrum analyzer.

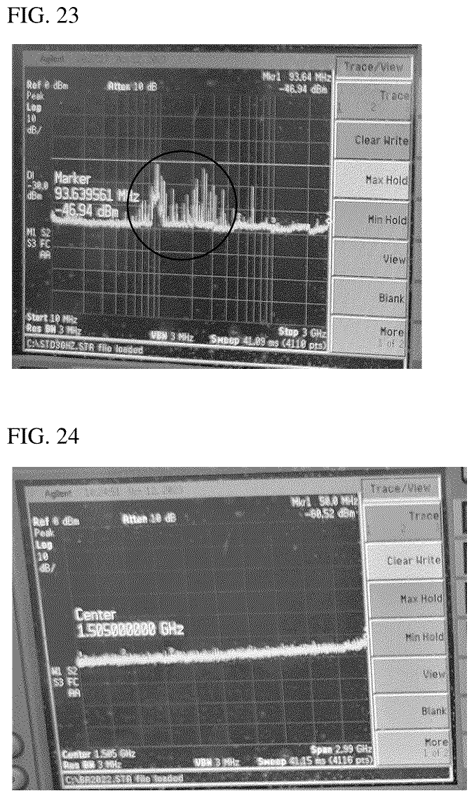

FIG. 23 is a spectrum analysis result of a cable to which an electromagnetic wave absorbing sheet is not applied and FIG. 24 is a spectrum analysis result of a cable to which an electromagnetic wave absorbing sheet according to an embodiment is applied.

As a result, referring to FIG. 23, in the case of a cable which does not have an electromagnetic wave absorbing sheet, as it was illustrated by a circle, it was confirmed that the electromagnetic wave of some frequency was significantly radiated.

In contrast, referring to FIG. 24, in the case of a cable to which the electromagnetic wave absorbing sheet is applied, the radiation of the electromagnetic wave was not specifically observed in all frequency bands.

The electromagnetic wave absorbing sheet according to various embodiments of the present disclosure has a high permeability in a high frequency band. The electromagnetic wave absorbing sheet according to various embodiments of the present disclosure has an excellent electromagnetic wave shielding effect. The electromagnetic wave absorbing sheet according to various embodiments of the present disclosure has an excellent electromagnetic wave absorbing effect. The electromagnetic wave absorbing sheet according to various embodiments of the present disclosure may effectively shield the electromagnetic interference. The electromagnetic wave absorbing sheet according to various embodiments of the present disclosure may be applied to various cables, conducting wires, electric wires, and the like which require the electromagnetic wave shielding.

According to the method for manufacturing an electromagnetic wave absorbing sheet according to various embodiments of the present disclosure, an electromagnetic wave absorbing sheet having a high permeability in a high frequency band may be manufactured. According to the method for manufacturing an electromagnetic wave absorbing sheet according to various embodiments of the present disclosure, an electromagnetic wave absorbing sheet having an excellent electromagnetic wave shielding effect may be manufactured. According to the method for manufacturing an electromagnetic wave absorbing sheet according to various embodiments of the present disclosure, an electromagnetic wave absorbing sheet having an excellent electromagnetic wave absorbing effect may be manufactured.

The effects of the present disclosure are not limited to those mentioned above, and other effects not mentioned can be clearly understood by those having ordinary skill in the art from the following description.

Embodiments of the present disclosure have been described above together with the drawings. However, this is just illustrative and the present disclosure is not limited by the above-described embodiments and the contents of the drawings.

It may be apparent to those having ordinary skill in the art that modifications may be made to the present disclosure within the scope of the disclosed technical spirit. The described embodiments should be considered as a part of the present disclosure, and the scope of the present disclosure should not be limited to the described embodiments.

The scope of the present disclosure should be determined by the technical spirit described in the claims. In addition, even though the actions or effects according to the configuration are not explicitly described while explaining embodiments of the present disclosure, it is apparent that the actions or effects predictable by the configuration should naturally be recognized as the present disclosure.

What is claimed is:

1. An electromagnetic wave absorbing sheet, comprising:
magnetic powders oriented in a direction.

2. The electromagnetic wave absorbing sheet according to claim 1, wherein the magnetic powders are oriented in a same magnetization direction.

3. The electromagnetic wave absorbing sheet according to claim 1, wherein the magnetic powders include at least any one of sendust powder, ferrite powder, chromium powder, carbonyl iron powder, or nanocrystalline ribbon powder.

4. The electromagnetic wave absorbing sheet according to claim 1, wherein an average particle size D50 of the magnetic powders is in a range of 10 μm to 70 μm.

5. The electromagnetic wave absorbing sheet according to claim 1, wherein the magnetic powders are comprised in an amount in a range of 80 wt % to 90 wt % based on a weight of the electromagnetic wave absorbing sheet.

6. The electromagnetic wave absorbing sheet according to claim 1, wherein the magnetic powders have a planar shape.

7. The electromagnetic wave absorbing sheet according to claim 1, comprising:
a base material; and
an electromagnetic wave absorbing layer comprising the magnetic powders,
wherein a thickness of the electromagnetic wave absorbing layer is in a range of 100 μm to 300 μm.

8. A method for manufacturing an electromagnetic wave absorbing sheet, the method comprising:
preparing an electromagnetic wave absorbing composition comprising magnetic powders; and
forming the electromagnetic wave absorbing composition on a base material,
wherein in forming the electromagnetic wave absorbing composition on the base material, the magnetic powders are oriented.

9. The method according to claim 8, wherein forming the electromagnetic wave absorbing composition on the base material comprises:
applying a magnetic field to the electromagnetic wave absorbing composition.

10. The method according to claim 8, wherein a magnetic flux density of the magnetic field is in a range of 0.25 T to 0.50 T.

11. The method according to claim 8, wherein forming the electromagnetic wave absorbing composition on the base material comprises:
applying a pressure to the electromagnetic wave absorbing composition.

12. The method according to claim 8, in forming the electromagnetic wave absorbing composition on the base material, the magnetic powders are oriented in a same magnetization direction.

13. The method according to claim 8, wherein the magnetic powders include at least any one of sendust powder, ferrite powder, chromium powder, carbonyl iron powder, or nanocrystalline ribbon powder.

14. The method according to claim 8, wherein the magnetic powders have a planar shape.

15. A cable, comprising:
a conductor; and
an electromagnetic wave absorbing sheet disposed on the conductor and comprising magnetic powders,
wherein the magnetic powders are oriented in a direction in the electromagnetic wave absorbing sheet.

16. The cable according to claim 15, wherein the magnetic powders are oriented in a direction intersecting a current direction of the conductor.

17. The cable according to claim 15, wherein the magnetic powders are oriented in a direction corresponding to a magnetic induction direction formed by the conductor.

18. The cable according to claim 15, wherein the magnetic powders include at least any one of sendust powder, ferrite powder, chromium powder, carbonyl iron powder, or nanocrystalline ribbon powder.

19. The cable according to claim 15, wherein the magnetic powders have a planar shape.

20. The cable according to claim 15, wherein the magnetic powders are comprised in an amount in a range of 80 wt % to 90 wt % based on a weight of the electromagnetic wave absorbing sheet.
